(19) United States
(12) Patent Application Publication
(10) Pub. No.: US 2013/0048494 A1
(43) Pub. Date: Feb. 28, 2013

(54) SPUTTERING DEVICE

(71) Applicants: Yukio Kikuchi, Chigasaki-shi (JP); Kenichi Imakita, Chigasaki-shi (JP)

(72) Inventors: Yukio Kikuchi, Chigasaki-shi (JP); Kenichi Imakita, Chigasaki-shi (JP)

(73) Assignee: ULVAC, INC., Chigasaki-shi, Kanagawa (JP)

(21) Appl. No.: 13/637,091

(22) PCT Filed: Mar. 23, 2011
(86) PCT No.: PCT/JP2011/056932

§ 371 Date: Nov. 8, 2012

(30) Foreign Application Priority Data
Mar. 29, 2010 (JP) 2010-076312

(51) Int. Cl. C23C 14/34; C23C 14/08

(52) U.S. Cl. 204/298.13

(57) ABSTRACT

A sputtering device includes a vacuum chamber accommodating a substrate stage which rotates a substrate having a film formation surface. A target that has a sputtered surface formed from magnesium oxide is provided in a circumferential direction of the substrate. An angle of a normal to the film formation surface of the substrate and a normal to the sputtered surface of the target is defined as an angle of inclination θ for the target, and the target is disposed such that the angle of inclination θ satisfies −50+φ<θ<−35+φ. Here, φ is an angle represented by φ=arctan(W/H); H represents the height from the center of the substrate to the center of the target; and W represents the width from the center of the substrate to the center of the target.

### TECHNICAL FIELD

The present invention relates to a sputtering device that rotates a substrate and sputters a target having a center point at a position that differs from a rotation axis of the substrate while rotating the substrate.

### BACKGROUND ART

Patent document 1 describes an example of a tunnel magnetic resistance element known in the prior art that uses of a tunnel magnetic resistance effect. A tunnel magnetic resistance element generally includes a fixed ferromagnetic layer, which has a fixed magnetization direction, a free ferromagnetic layer, which has a magnetization direction that can be varied freely by an external magnetic field, and a tunnel barrier layer, which is located between the fixed ferromagnetic layer and the free ferromagnetic layer. The fixed ferromagnetic layer, the free ferromagnetic layer, and the tunnel barrier layer are laminated together. When the direction of magnetization of the free ferromagnetic layer is parallel to the direction of magnetization of the fixed ferromagnetic layer, the transmissivity of electrons in the tunnel barrier layer becomes high. Accordingly, the tunnel magnetic resistance value becomes relatively low. On the other hand, when the direction of magnetization of the free ferromagnetic layer is not parallel to the direction of magnetization of the fixed ferromagnetic layer, the transmissivity of electrons in the tunnel barrier layer is low. Accordingly, the tunnel magnetic resistance value becomes relatively high. Hence, a low state of tunnel magnetic resistance value and a high state of tunnel magnetic resistance value can be selectively stored in one tunnel magnetic resistance element. In other words, one-bit information can be stored in one tunnel magnetic resistance element.

To express this magnetic resistance effect, a film thickness of about several nanometers is generally required as the tunnel barrier layer between the two ferromagnetic layers. To form a thin film of several nanometers uniformly, an oblique incidence type sputtering device is widely used as described, for example, in patent document 2. FIG. 9 is a schematic diagram showing the layout of a target and a substrate in an oblique incidence type sputtering device. As shown in FIG. 9, in the oblique incidence type sputtering device, a target 102 is arranged so that a normal L1 to a film formation surface 101s of a substrate 101 and a normal L2 to a sputtered surface 102s of a target 102 form a predetermined angle θt. While rotating the substrate 101 about a center axis C extending in a thickness direction of the substrate 101, the target 102 having a center point at a position different from the rotation axis is sputtered.

Here, the number of sputter particles sputtered from the sputtered surface 102s of the target 102 is not always uniform within the plane of the sputtered surface 102s, but rather biased within the plane of the sputtered surface 102s in accordance with the distribution of concentration of plasma formed near the sputtered surface 102s. Thus, when the target 102 is sputtered with the film formation surface 101s of the substrate 101 being opposed in a still state to the sputtered surface 102s of the target 102, the film thickness is biased in accordance with the release distribution of sputter particles within the plane of the sputtered surface 102s. In contrast, as described above, when the substrate 101 is rotated, the distribution of sputter particles within the sputtered surface 102s is dispersed in the circumferential direction of the substrate 101. Thus, the distribution of film thickness becomes uniform. Accordingly, in the oblique incidence type sputtering device, as compared with a configuration that does not rotate the substrate 101, a high uniformity of film thickness can be obtained on the film formation surface 101s of the substrate.

### PRIOR ART DOCUMENT

Patent Document 1: Japanese Patent Application Laid-Open No. 2008-41716

Patent document 2: Japanese Patent Application Laid-Open No. 2005-340721

### SUMMARY OF THE INVENTION

### Problems to be Solved by the Invention

As an index for evaluating an output voltage of a tunnel magnetic resistance element, generally, a magnetic resistance ratio (MR ratio) is used. The MR ratio is determined in the following expression (A), where Rp is the tunnel magnetic resistance value when the directions of magnetization of the two ferromagnetic layers are parallel to each other, and Rap is the tunnel magnetic resistance value when the directions of magnetization of the two ferromagnetic layers are not parallel to each other. The larger the MR ratio, the greater the output voltage of the tunnel magnetic resistance element becomes. Thus, a technique for increasing the MR ratio is desired in this device, which is required to be more miniaturized and sophisticated.

(Rap−Rp)/Rp Expression (A)

Recently, as one of the techniques for increasing the MR ratio, the use of a magnesium oxide (MgO) film of (001) orientation as the tunnel barrier layer is known.

FIG. 10 is a schematic diagram showing an angle of incidence on the substrate 101 of sputter particles SP released from a center point 102c of the sputtered surface 102s in the oblique incidence type sputtering device. As shown in FIG. 10, when an MgO film is formed by the oblique incidence type sputtering device, in a region Zc of the substrate 101 near the center axis C, the relative position of the sputtered surface 102s to the film formation surface 101s varies in the circumferential direction of the substrate 101 in accordance with the rotation of the substrate 101. Thus, in the angle components of the angle of incidence θc of sputter particles reaching the region Zc, angle components along the circumferential direction of the substrate 101 change in accordance with the rotation of the substrate 101. Further, in a region Ze near an outer edge of the substrate 101, the relative position of the sputtered surface 102s to the film formation surface 101s changes largely not only in the circumferential direction of the substrate 101 but also in the radial direction of the substrate 101 in accordance with the rotation of the substrate 101. As a result, the angle components of the angle of incidence of sputter particles SP reaching the region Ze further varies greatly as compared with the case of the region Zc.

For example, in the region Ze, at point 101a on a circumferential edge closest to the center point 102c of the sputtered surface 102s, an angle formed by a straight line, extending through the center point 102c and the point 101a, and a normal L1 to the film formation surface 101s is the most proximal angle of incidence Oea. Further, at point 101b on the circumferential edge farthest from the center point 102c of the sputtered surface 102s, an angle formed by a straight line, extending through the center point 102c and the point 101b, and a normal L1 to the film formation surface 101s is a farthest angle of incidence θeb. The difference between the most proximal angle of incidence θea and the farthest angle of incidence θeb is approximated by a solid angle θs, the apex of which is the center point 102c. Under a condition in which the target 102 is arranged in such a manner, at the angle of incidence of sputter particles reaching each point on the circumferential edge of the substrate 101, a variation corresponding to the difference between the most proximal angle of incidence θea and the farthest angle of incidence θeb is generated in accordance with the rotation of the substrate 101.

The angle of incidence of sputter particles SP on the film formation surface (face side) 101s of the substrate 101 is an element for determining the arrangement of sputter particles SP on the film formation surface 101s of the substrate 101. It is also an important element for determining the orientation of the MgO film. Accordingly, if the angle of incidence always differs within a period of a single rotation of the substrate 101, the peak intensity of the (001) orientation of the MgO film is weakened. In particular, in the vicinity of the circumferential edge of the substrate 101, the degree of weakening of the peak intensity is greater. This is a large drawback for increasing MR ratio of tunnel magnetic resistance elements formed in the substrate 101.

In the film characteristics of the MgO film, aside from the orientation described above, the uniformity of film thickness within the plane of the substrate is an equally important element for determining the MR ratio of the magnetic resistance element. In the case where enhancement of MR ratio by using the MgO film in the tunnel barrier film is strongly demanded, a uniform film thickness distribution of the MgO film in the substrate is desired in addition to enhancement of orientation strength of the MgO film within the plane of the substrate and uniformity of its in-plane distribution from the viewpoint of improving in-plane distribution of film characteristics of the MgO film.

The problems relating to the in-plane distribution of film characteristics are not limited to when using the MgO film as the tunnel barrier layer of the magnetic resistance element but also occur when the MgO film is used in other elements or other devices. That is, the improvement of in-plane distribution of film characteristics of the MgO film contributes greatly to enhancement of performance of elements and devices using the MgO film and is not limited to the tunnel barrier layer.

Accordingly, it is an object of the present invention to provide a sputtering device capable of enhancing the in-plane distribution of film characteristics of MgO film.

### Means for Solving the Problems

Means for solving the above problems and its effects will now be described.

A first aspect of the present invention includes a vacuum chamber accommodating a substrate stage that rotates a disk-shaped substrate, which includes a film formation surface, in a circumferential direction of the substrate. A target is arranged in the circumferential direction of the substrate and includes a sputtered surface formed from magnesium oxide and exposed to the interior of the vacuum chamber. An angle of a normal to the film formation surface of the substrate and a normal to the sputtered surface of the target is defined as an inclination angle θ. The inclination angle θ of the target is 0° when the sputtered surface is opposed to the film formation surface and the normal to the sputtered surface is parallel to the normal to the film formation surface. The inclination angle θ is positive when the sputtered surface is directed inward into the film formation surface. The inclination angle θ is negative when the sputtered surface is directed outward from the film formation surface. When a height from a center of the substrate to a center of the target is H, and a width from the center of the substrate to the center of the target is W, an angle φ expressed by the height H and the width W is defined as φ=arctan(W/H). The target is arranged so that the inclination angle θ of the target satisfies the relationship of −50+φ<θ<−35+φ.

According to the first aspect, regardless of the component material of the target, the relative position of the target center to the substrate center is determined by the angle φ.

Generally, the release frequency of sputter particles released from the sputtered surface varies in accordance with the angle (release angle) between the normal to the sputtered surface and an advancing direction of sputter particles released from the sputtered surface. When considering this point, the inclination angle θ is determined as an angle of the film formation surface and the direction determined by the release angle of relatively high release frequency on the sputtered surface of the target (high release angle).

The inventors of the present invention, using a target formed from magnesium oxide, have found that the release angle having a relatively high frequency of release is about 25° from numerical calculations and measurements. Further, the present inventors, in order to obtain a favorable distribution of film characteristics in the plane of the substrate, repeated studies and researches about where to arrange the target center relative to the substrate center and how to direct the direction determined by the high release angle on the film formation surface. When the angle φ and the inclination angle θ satisfy the relationship shown in expression (1), it has been discovered that a favorable distribution of film characteristics may be obtained within the plane of the substrate. Here, the favorable distribution includes a particularly favorable range in which the film thickness distribution is within ±1% within the plane of the substrate.

−50+φ<θ<−35+φ Expression (1)

Expression (1) determines the relationship of the position of the target, which is determined by the two parameters of height H and width W, and the inclination angle θ of the target at that position. This expression was obtained by investigating the actual film thickness distribution in two typical cases described below. In the two typical cases shown below, it has been confirmed that a favorable film thickness distribution was obtained as far as the relationship of expression (1) is satisfied. When the inclination angle θ does not satisfy the relationship of expression (1), it has been confirmed that favorable film thickness distribution was not obtained. One of the two typical cases used to obtain the relationship expression is when the target height was relatively low, the target width was relatively large, and the target center was deviated in a lateral direction from the substrate center. The other case is when the target height was relatively large, the target width was relatively small, and the target center was deviated in a longitudinal direction from the substrate center.

For example, when the height H was 170 mm and the width W was 190 mm, an angle φ determined from the height H and the width W is calculated. At different inclination angles θ, the distribution of film characteristics was actually evaluated, and the film thickness distribution of the target inclination angle θ that obtained favorable distribution of film characteristics was determined. Here, it was found that a favorable distribution of film characteristics was obtained when the difference between an angle (90−25)+θ of a direction determined by the high release angle and a normal direction of film formation surface and angle φ that is (90−25)+θ−φ was about 15° or greater.

For example, when the height H was 210 mm and the width W was 130 mm, it was found that a favorable distribution of film characteristics was obtained when the difference between an angle (90−25)+θ of a normal direction of the film formation surface and the high release direction and angle φ that is (90−25)+φ was about 30° or less.

Further, when the target is arranged at other positions, the angle φ was obtained in the same manner as described above and the inclination angle of the target that obtained a favorable film thickness distribution was obtained. It was also found that each inclination angle satisfies the relationship of 15°<65+θ−φ<30°, that is, satisfies expression (1). From these results, the relationship shown in expression (1) as the relationship of the substrate position and the target inclination angle θ capable obtaining a favorable film thickness distribution was obtained as an empirical rule.

It was also found that a favorable film thickness distribution was not obtained when inclining the target out of the range of the inclination angle determined by the height H and the width W. For example, when the height H was 190 mm and the width W was 160 mm, the target inclination angle θ capable of obtaining a favorable film thickness distribution was −9.9°<θ<5.1°. In such target configuration, when 6° is selected as an angle not included in the optimum range of inclination angle θ, the film thickness distribution of the formed MgO film was about ±5%. In short, as far as the inclination angle θ of the target does not satisfy expression (1) at a certain target position, it was found that a favorable film thickness distribution was not obtained. This proves that the empirical rule is effective.

In this manner, the present inventors intensively studied the release frequency of magnesium oxide for each release angle and found that a uniform and favorable film thickness can be obtained as far as the inclination angle θ is in a range satisfying the relationship of −50+φ<θ<−35+φ. In the first aspect of the present invention, the angle θ formed between a normal to the film formation surface and a normal to a sputtered surface is in a range of −50+φ<θ<−35+φ. Therefore, uniformity is achieved in distribution of film thickness in magnesium oxide film.

A second aspect of the present invention includes a vacuum chamber accommodating a substrate stage that rotates a disk-shaped substrate, which includes a film formation surface, in a circumferential direction of the substrate. A plurality of targets are arranged in the circumferential direction of the substrate. Each of the targets includes a sputtered surface formed from magnesium oxide and exposed to the interior of the vacuum chamber. A point on a circumferential edge of the substrate that is closest to a center point of the sputtered surface is defined as a proximal point. An angle of a straight line, extending through the center point of the sputtered surface and the proximal point of the substrate, and the film formation surface of the substrate is defined as a most proximal angle of incidence. A point on the circumferential edge of the substrate that is farthest from the center point of the sputtered surface is defined as a far point. An angle of a straight line, extending through the center point of the sputtered surface and the far point of the substrate, and the film formation surface of the substrate is a farthest angle of incidence. The plurality of targets are arranged so that the most proximal angle of incidence of each of the targets is smaller than the farthest angle of incidence of the other targets. The plurality of targets are sputtered at the same time.

When sputtering a single target, which is arranged where the center point of the sputtered surface is separated from the rotation axis of a substrate, while rotating the substrate, most of the sputter particles deposited on a point on the substrate circumferential edge have an angle of incidence as determined in (A) or (B) below in accordance with the distance from the center point of the sputtered surface to the point on the substrate circumferential edge. Accordingly, when forming a film by using a single target, when the substrate rotates once, sputter particles of (A) or (B) are deposited on the entire surface on the substrate circumferential edge.

(A) Sputter particles of small angle of incidence are deposited at a point of the substrate close to the target.

(B) Sputter particles of large angle of incidence are deposited at a point of the substrate far from the target.

When film forming is terminated in the midst of a rotation period, during the final cycle of the substrate, in the substrate circumferential edge, the sputter particles of (A) may not be deposited at a certain portion or the sputter particles of (B) may not be deposited at a certain portion. During execution of film forming process by sputtering, in accordance with the rotation period of the substrate, a film may be deposited at a different angle of incidence to the substrate. This obstructs improvement in orientation. Thus, the regularity of the arrangement of sputter particles and or the orientation of the thin film formed by depositing sputter particles may be largely sacrificed.

In this respect, in the second aspect, a plurality of magnesium oxide (MgO) targets are arranged in the circumferential direction of the substrate, and the most proximal angle of incidence of each of the plurality of targets is smaller than the farthest angle of incidence of other targets. In such a configuration, sputter particles of a small angle of incidence are simultaneously deposited in a portion at the substrate circumferential edge close to each target, and sputter particles of a large angle of incidence are simultaneously deposited in a portion on the substrate circumferential edge far from each target. Accordingly, even in the midst of a single rotation of the substrate, the sputter particles (A) or (B) are deposited on the entire surface of the substrate circumferential edge. Hence, when film forming is terminated in the midst of a rotation period, the area of the portion not forming the sputter particles (A) or the area of the portion not forming the sputter particles (B) may be reduced by using the plurality of targets. As a result, regardless of whether a desired orientation is obtained by the sputter particles (A) or a desired orientation is obtained by the sputter particles (B), the strength of orientation on the substrate circumferential edge may be improved.

When sputtering a target while rotating the substrate by arranging the center point of the sputtered surface at a position separated from the rotation axis of the substrate for a single target, the incidence direction of sputter particles deposited on the center point of the substrate varies in accordance with the rotation angle of the substrate of the components in the circumferential direction of the substrate. Accordingly, as compared with the angle of incidence of sputter particles at the center point of the substrate, variations are small. However, the angle of incidence of sputter particles at the center point of the substrate becomes the same angle of incidence as the substrate rotates once. In this respect, in the second aspect, a plurality of targets are arranged in the circumferential direction of the substrate. Hence, even in the midst of a single rotation of the substrate, sputter particles reach near the center point of the substrate at an incidence direction that is the same or nearly the same in angle components in the circumferential direction of the substrate. As a result, the strength of orientation near the center point of the substrate can also be increased.

In a third aspect of the present invention according to the second aspect of the sputtering device, an angle of a normal to the film formation surface of the substrate and a normal to the sputtered surface of the targets is set as an inclination angle θ, the inclination angle θ of the target is 0° when the sputtered surface is opposed to the film formation surface and the normal to the sputtered surface and the normal to the film formation surface are parallel to each other, the inclination angle θ is positive when the sputtered surface is directed inward into the film formation surface, the inclination angle θ is negative when the sputtered surface is directed outward from the film formation surface, when a height from a center of the substrate to a center of each of the targets is H and a width from the center of the substrate to the center of each of the targets is W, an angle φ expressed by the height H and the width W is defined as φ=arctan (W/H), and the target is arranged so that the inclination angle θ of the target satisfies the relationship of −50+φ<θ<−35+φ.

When forming a film by using a single target, whenever the substrate rotates once, the sputter particles (A) and the sputter particles (B) are deposited on the entire surface of the substrate circumferential edge to a thickness corresponding to the release frequency. As a result, regardless of the rate of frequency of (A) and frequency of (B), until the film forming is terminated, sputter particles of high emission frequency and sputter particles of high emission frequency are alternately deposited on the substrate circumferential edge.

In this respect, according to the third aspect, the sputter particles (A) and the sputter particles (B) are released simultaneously from different targets at points on the substrate circumferential edge. In this state, sputter particles having a small angle of incidence and released from nearby targets are scattered, in particular, when colliding against the following particles (C1) and (C2) before reaching the film formation surface.

(C1) Gas for releasing sputter particles from the sputtered surface.

(C2) Sputter particles having a large angle of incidence and released from other targets.

Sputter particles having a large angle of incidence and released from remote targets are scattered, in particular, when colliding against the following particles (C3) to (C5) before reaching the film formation surface.

(C3) Gas for releasing sputter particles from the sputtered surface.

(C4) Sputter particles having a large angle of incidence and released from other targets. (C5) Sputter particles having a small angle of incidence and released from other targets.

As described above, compared with sputter particles having a small angle of incidence, the sputter particles having a large angle of incidence include more particles subject to colliding ((C3) to (C5)). Thus, the distance to the film formation surface is long, and the particles are more likely to be scattered. As a result, sputter particles having a small angle of incidence are, as compared with sputter particles having a large angle of incidence, are more likely to be deposited on the film formation surface. Hence, when the sputtered surface is arranged relative to the film formation surface so that the sputter particles released at a release angle having a high release frequency can reach the sputtered surface at a smaller angle of incidence, more sputter particles having a small angle of incidence may reach near the substrate, and the strength of orientation by sputter particles having a smaller angle of incidence increases.

The inventors of the present invention have found that the release angle having a relatively high release frequency in the target formed from magnesium oxide is about 25° based on numerical calculations and measurements and studied the range of the inclination angle from the viewpoint of the particles released at a release angle having a relatively high release frequency striking at a small angle of incidence. Further, it was found that as far as the inclination angle θ is in the range of “−50+φ<θ<−35+φ,” (001) orientation of high strength, an excellent uniformity within the substrate plane, and a favorable uniformity of film thickness can be obtained. According to the third aspect, the angle θ formed between a normal to the film formation surface and a normal to a sputtered surface is in a range of “−50+φ<θ<−35+φ.” Therefore, uniformity is obtained in the distribution of the film thickness in the magnesium oxide film, and (001) orientation of high strength is uniformly obtained in the magnesium oxide film.

In a fourth aspect of the present invention according to the sputtering device of the first to third aspects, the internal pressure of the vacuum chamber is 10 mPa or greater and 130 mPa or less.

When the internal pressure of the vacuum chamber increases, the sputter particles are apt to being scattered due to particles (C1) to (C5). When the internal pressure of the vacuum chamber decreases, the scattering of sputter particles due to particles (C1) to (C5) is less likely to occur. In a configuration in which the sputtered surface is arranged relative to the film formation surface so that the sputter particles released at a release angle of high release frequency reaches the sputtered surface at a small angle of incidence, and the effects described above become more prominent when the amount of scattering caused by the particles (C1) and (C2) is small and the amount of scattering caused by the particles (C3) to (C5) is large.

The present inventors have studied the film forming pressure and the (001) orientation of the magnesium oxide film from the viewpoint described above and found that a more favorable film characteristic can be obtained when the film forming pressure is 10 mPa or greater and 130 mPa or less. In the fourth aspect, the film forming pressure is 10 mPa or greater and 130 mPa or less. Thus, the film characteristics of the magnesium oxide film can be further improved.

In a fifth aspect of the present invention according to the sputtering device of the second to fourth aspects, the inclination angle θ that is an angle of a normal to the film formation surface of the substrate and a normal to the sputtered surface of each of the targets is the same in the plurality of targets.

According to the fifth aspect, the inclination angles θ of the plurality of targets are the same. Thus, even in the midst of one rotation of the substrate, the portion on which the sputter particles (A) deposit and the portion on which the sputter particles (B) deposit have substantially the same orientation on the substrate circumferential edge. Accordingly, the strength of orientation and the in-plane uniformity of orientation can be further increased.

In a sixth aspect of the present invention according to the sputtering device of the second to fifth aspects, the plurality of targets are arranged at equal intervals in the circumferential direction of the substrate.

According to the sixth aspect, the plurality of targets are arranged at equal intervals on the substrate circumferential edge. Thus, sputter particles having the same angle of incidence reach the substrate circumferential edge at equal intervals. This decreases the biasing in the orientation at the substrate circumferential edge, and the in-plane uniformity of orientation can be further increased.

### BRIEF DESCRIPTION OF THE DRAWINGS

FIG. 1(a) is a schematic diagram of a sputtering device according to one embodiment of the present invention;

FIG. 1(b) is a plan view showing the positional relationship of a substrate and a target in the sputtering device of FIG. 1(a);

FIG. 2(a) is a schematic diagram showing a release angle distribution of sputter particles released from a sputtered surface of a magnesium oxide target;

FIG. 2(b) is a schematic diagram showing a release angle distribution of sputter particles released from a sputtered surface of a metal target;

FIG. 3 is a schematic diagram showing an angle of incidence at a substrate of sputter particles released from a center point of a sputtered surface of a target arranged in the sputtering device in FIG. 1;

FIG. 4 is a graph showing the relationship of the distance from the substrate center and orientation strength;

FIG. 5 is a graph showing the relationship of the distance from substrate center and magnetic resistance ratio;

FIG. 6 is a graph showing the relationship of distance from substrate center and orientation strength;

FIG. 7 is a graph showing the relationship of the tilt angle and film thickness uniformity;

FIG. 8 is a graph showing the relationship of the tilt angle and film thickness uniformity;

FIG. 9 is a schematic diagram of a prior art sputtering device; and

FIG. 10 is a schematic diagram showing an angle of incidence at a substrate of sputter particles released from a center point of a sputtered surface of a target arranged in the prior art sputtering device.

### EMBODIMENTS OF THE INVENTION

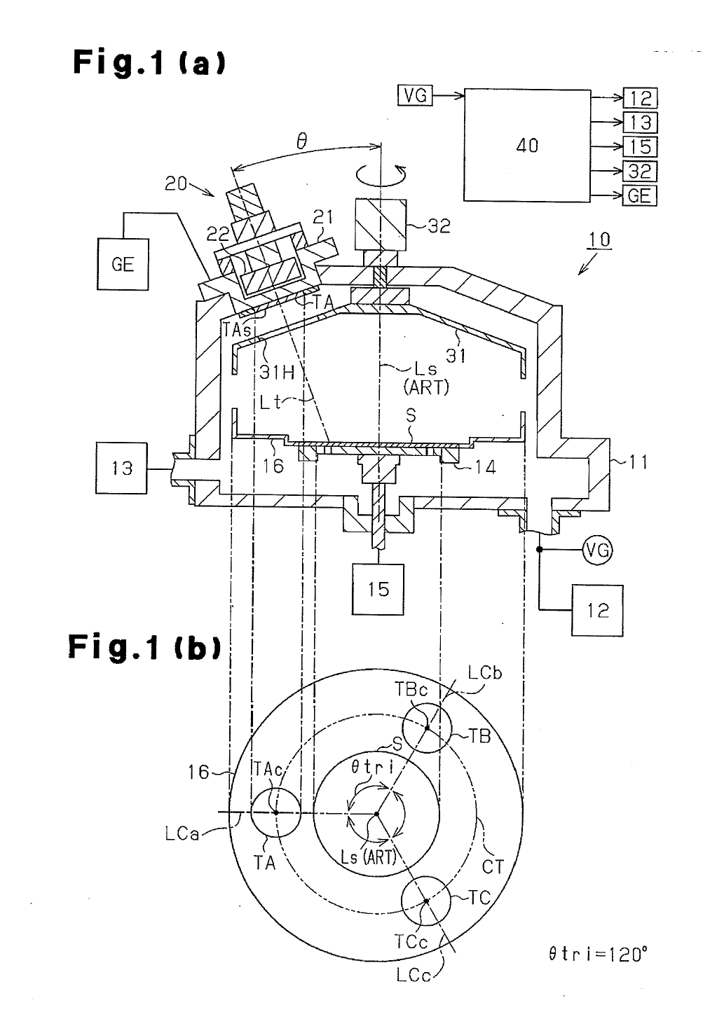

A sputtering device according to a first embodiment of the present invention will now be described with reference to FIGS. 1 to 6.

FIG. 1 schematically shows the configuration of the sputtering device. As shown in FIG. 1(a), a sputtering device 10 includes a vacuum chamber 11. The vacuum chamber 11 includes an exhaust device 12 formed by a cryogenic pump or the like to discharge gas from the interior of the vacuum chamber 11. A pressure detecting device VG is connected between the exhaust device 12 and the vacuum chamber 11 to detect the internal pressure of the vacuum chamber 11. When the exhaust device 12 is operated, the pressure is reduced in the vacuum chamber 11, and the present internal pressure is detected by the pressure detecting device VG.

The vacuum chamber 11 is connected to a gas supply device 13, which includes a mass flow controller and the like and supplies the vacuum chamber 11 with a rare gas, such as argon (Ar), krypton (Kr), and xenon (Xe), at a predetermined flow rate. During execution of a normal exhaust process by the exhaust device 12, when the gas supply device 13 supplies the rare gas to the vacuum chamber 11, the pressure of the vacuum chamber 11 is adjusted to a predetermined pressure, for example, 10 mPa or greater and 130 mPa or less.

A substrate stage 14 is arranged to hold a disk-shaped substrate S at the bottom side of the interior of the vacuum chamber 11. The substrate stage 14 is coupled to an output shaft of a substrate rotating device 15 that rotates the substrate stage 14 and the substrate S. The substrate rotating device 15 rotates the substrate stage 14. This rotates the substrate S in its circumferential direction about the center of the substrate rotation axis ART, which extends through the center of the substrate S and which is parallel to normal Ls to the surface of the substrate S. In this state, the destinations of sputter particles flying toward the substrate S are distributed over the entire circumference of the substrate S. This increases the film thickness uniformity of deposits on the substrate S. The substrate S held on the substrate stage 14 is, for example, a silicon (Si) substrate, an AlTiC substrate, or glass substrate. The substrate S includes a film formation surface formed to obtain an orientation of deposits on the substrate S. When the deposit is a magnesium oxide (MgO) film, in order to obtain (001) orientation of the MgO film, the film formation surface of the substrate S is formed from non-crystalline cobalt iron boron (CoFeB).

An adhesion prevention plate 16, which is cylindrical and has a closed bottom end, is arranged along the outer circumference of the substrate S in the vacuum chamber 11. The adhesion prevention plate 16 prevents the sputter particles flying toward the surrounding of the substrate stage 14 or the bottom side of the vacuum chamber 11 from adhering to the substrate stage 14 or the vacuum chamber 11.

A cathode 20, which generates plasma in the vacuum chamber 11, is arranged on the top of the vacuum chamber 11. The cathode 20 includes a backing plate 21, and the backing plate 21 is electrically connected to a high-frequency power source GE that outputs a high-frequency electric power of, for example, 13.56 MHz. Further, a first target TA opposing the substrate S is electrically connected to the backing plate 21. The first target TA includes a sputtered surface TAs, the mainly component of which is, for example, MgO. The sputtered surface TAs is exposed to the interior of the vacuum chamber 11. The first target TA is arranged so that the inclination angle of a normal Lt to the sputtered surface TAs of the first target TA and the normal Ls to the film formation surface of the substrate S, that is, the tilt angle θ of the sputtered surface TAs of the first target TA and the film formation surface of the substrate S, may be, for example, 22°. Hereinafter, the normal Lt is referred to as the “target normal Lt”, and the normal Ls is referred to as the “substrate normal Ls”.

When the target normal Lt and the substrate normal Ls are parallel, the tilt angle θ is set as 0°. When the sputtered surface TAs is directed inward into the film formation surface as shown in FIG. 1, the tilt angle θ is set to be positive. When the sputtered surface TAs is directed outward from the film formation surface, the tilt angle θ is set to be negative.

A magnetic circuit 22 is arranged to sandwich the backing plate 21 with the first target TA. When the magnetic circuit 22 is driven in a state in which the backing plate 21 is supplied with high-frequency electric power from the high-frequency power source GE, the magnetic circuit 22 forms a magnetron magnetic field at the sputtered surface TAs of the first target TA. The magnetron magnetic field contributes to plasma generation near the sputtered surface TAs of the first target TAC. This increases the plasma density and sputters the sputtered surface TAs with the ions of the rare gas.

As shown in FIG. 1(b), in addition to the first target TA, the vacuum chamber 11 of the sputtering device 10 in this embodiment includes a second target TB and a third target TC. The second target TB and the third target TC each include a sputtered surface formed from the same material as the first target TA, and the sputtered surface is exposed to the interior of the vacuum chamber 11. In the same manner as the sputtered surface of the first target TA, each of the second target TB and the third target TC is arranged so that the angle of the target normal Lt and the substrate normal Ls, that is, the tilt angle θ is, for example, 22°. Further, in the same manner as the first target TA, each of the second target TB and the third target TC is formed as a cathode with a backing plate, a high-frequency power source, and a magnetic circuit.

The first target TA, the second target TB, and the third target TC are arranged so that their centers TAc, TBc, and TCc are equally distanced from the center point Pc of the substrate S and arranged at equal intervals (equally distributed) along the circumferential direction of the substrate S. Thus, the centers TAc, TBc, and TCc of the first target TA, the second target TB, and the third target TC are arranged on a virtual circle CT concentric with the substrate S as viewed in a direction parallel to the substrate rotation axis ART. In addition, as viewed in a direction parallel to the substrate rotation axis ART, straight lines LCa, LCb, and LCc equally divide the center angle of the substrate S into three. The center TAc of the first target TA is located on the line LCa, the center TBc of the second target TB is located on the line LCb, and the center TCc of the third target TC is located on the line LCc. The angle θtri between the adjacent lines LCa, LCb, and LCc is 120°.

Near the targets TA, TB, and TC, a dome-shaped shutter 31, which opposes the substrate S and covers the upper part of the substrate S, is arranged immediately above the substrate stage 14. The shutter 31 is coupled to an output shaft of a shutter rotating device 32, which rotates and drives the shutter 31. The shutter 31 includes a plurality of openings 31H, which are capable of substantially exposing all of the sputtered surfaces of the targets TA, TB, and TC to the substrate S at the same time. The shutter rotating device 32 rotates the shutter 31 about the substrate rotation axis ART so that the openings 31H of the shutter 31 are opposed to the sputtered surfaces of the targets TA, TB, and TC. In this state, when high-frequency electric power is supplied to the backing plate 21, the targets TA, TB, and TC can be sputtered. When high-frequency electric power is not supplied to the backing plate 21 and the targets TA, TB, and TC are not sputtered, the sputtered surfaces of the targets TA, TB, and TC are covered by the shutter 31. This suppresses contamination of the sputtered surfaces.

The sputtering device 10 includes a control device 40, which control various processes, such as the pressure reduction process performed by the exhaust device 12, the gas supplying process performed by the gas supply device 13, and the high-frequency electric power supplying process performed by the high-frequency power source GE. For example, the control device 40 is electrically connected to the devices listed below and transmits and receives various signals.

The control device 40 is connected to the exhaust device 12 and outputs a start control signal, which starts the reduction process, and a termination control signal, which terminates the evacuating process.

The control device 40 is connected to the pressure detecting device VG and the gas supply device 13, receives an output signal from the pressure detecting device VG, and provides a flow rate control signal to the gas supply device 13 to adjust the internal pressure of the vacuum chamber 11 to a predetermined pressure.

The control device 40 is connected to the substrate rotating device 15 and outputs a start control signal, which starts the rotating process, and a termination control signal, which terminates the rotating process.

The control device 40 is connected to the shutter rotating device 32 and outputs a rotation control signal so that each opening is opposed to the corresponding target.

The control device 40 is connected to the high-frequency power source GE and outputs a power supply start control signal, which supplies a high-frequency electric power to each target, and a power supply stop control signal, which stops supplying high-frequency electric power to each target.

In the sputtering device 10, when a film forming process is started, the exhaust device 12 reduces the internal pressure of the vacuum chamber 11 to a predetermined pressure in response to a command from the control device 40. Then, a substrate transporting device (not shown) loads the substrate S into the vacuum chamber 11. When the substrate S is held on the substrate stage 14, the control device 40 drives the shutter rotating device 32 so that the openings 31H of the shutter 31 are arranged opposing the sputtered surface of the targets TA, TB, and TC. Further, the control device 40 drives the substrate rotating device 15 and rotates the substrate S around the substrate rotation axis ART.

When rotation of the substrate S is started, the control device 40 supplies the rare gas at a predetermined flow rate from the gas supply device 13 to the vacuum chamber 11 to adjust the internal pressure of the vacuum chamber 11 to a predetermined pressure. Then, the control device 40 supplies high-frequency electric power from each high-frequency power source GE to each target and starts sputtering the sputtered surfaces.

[Release Angle Distribution]

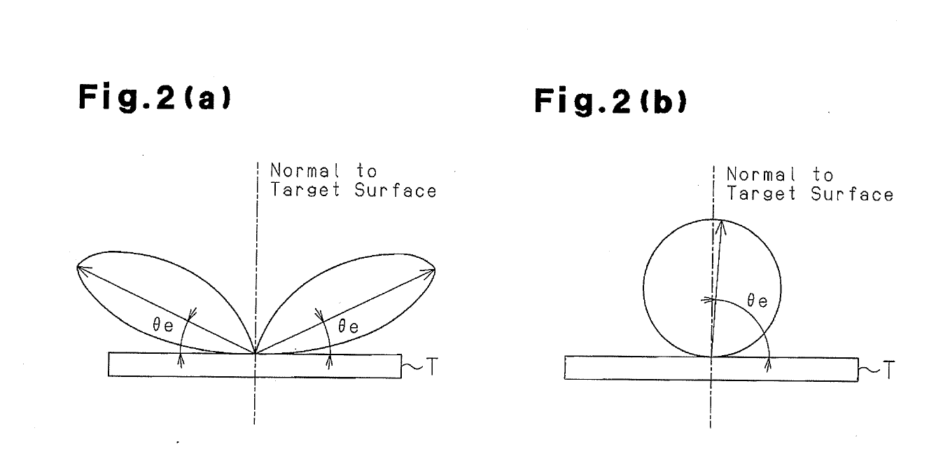

Referring to FIG. 2, the relationship of the release angle and release frequency of sputter particles released from a given point of a sputtered surface (release angle distribution) when the sputtered surface of the target is sputtered by argon, which is a rare gas, will now be described. FIG. 2(a) shows the result of a numerical calculation of the release angle distribution when sputtering the target T, the main component of which is an insulating material MgO. FIG. 2(b) shows the result of a numerical calculation of the release angle distribution when sputtering the target T, the mainly component of which is aluminum that is a metal material. The release angle distribution of each of MgO and aluminum is obtained by executing a simulation by using a Direct Simulation Monte Carlo (DSMC) process based on the erosion shape, which is the sputtered shape of the target T when film forming is performed under predetermined conditions. FIGS. 2(a) and 2(b) both show the release frequency for each release angle θe as a vector quantity. The origin of the graph is a collision point of sputter particles on the sputtered surface of the target. The vertical axis represents a direction parallel to the target normal Lt, and the horizontal axis represents a direction orthogonal to the target normal Lt.

As shown in FIG. 2(a), in the target T, the main component of which is MgO, a large amount of sputter particles are released at a release angle θe in a range of about 20° to 30° from the point of collision of sputter gas particles on the sputtered surface. In particular, most of the sputter particles are released at the release angle θe of about 25°. When the release angle θe is less than or greater than the range of the release angle θe, the release frequency of sputter particles decreases. In contrast, as shown in FIG. 2(b), in the target T, the main component of which is aluminum, a large amount of sputter particles are released at a release angle θe in a range of about 85° to 95°. The amount of sputter particles that are released becomes largest at the release angle θe of about 90°. When the release angle θe is less than or greater than the range of the release angle θe, the release frequency of sputter particles decreases.

As shown in FIGS. 2(a) and 2(b), the release frequency of sputter particles released from the sputtered surface of the target T is biased in accordance with the release angle θe. Such biasing differs between the materials of the target. The release angle θe shown in FIGS. 2(a) and 2(b) is obtained when argon gas is used as the sputtering gas. Thus, as long as the material of the target is the same, the release angle distribution is different if another gas, such as helium gas or xenon gas, is used as the sputtering gas. This is because the release angle distribution is in accordance with the mass ratio of sputtering particles such as Mg atoms, O atoms, and MgO molecules and the sputtering gas, such as argon ion, helium ion, and xenon ion.

[Arrangement of Targets]

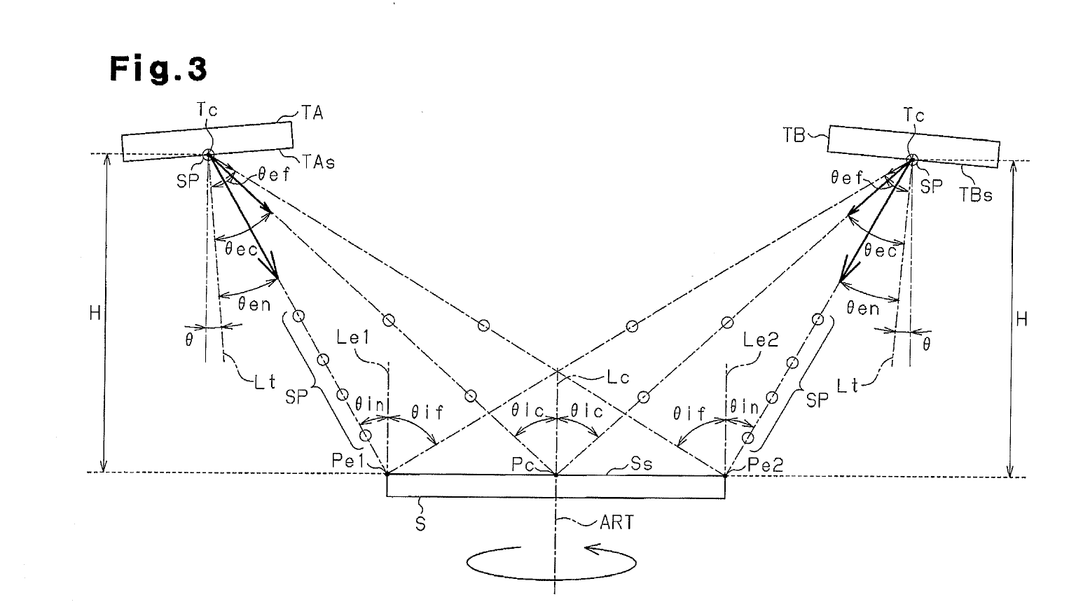

Referring next to FIG. 3, the arrangement of the targets TA, TB, and TC and the frequency the sputter particles released from the targets TA, TB, and TC reach the film formation surface will now be described. FIG. 3 schematically shows the release angle and angle of incidence of sputter particles SP released from a center point (reference point Tc) of the sputtered surface TAs of the first target TA and how the sputter particles reach the film formation surface Ss. FIG. 3 shows the arrangement of the first target TA and the second target TB and the process in which the sputter particles SP released from the first target TA and the second target TB reach the film formation surface Ss. The reaching process of the sputter particles SP shown in FIG. 3 is not limited to between the first target TA and the second target TB and is also the same between the first target TA and the third target TC, and between the second target TB and the third target TC. That is, the actions of the sputter particles shown in FIG. 3 occurs between any two of the targets, regardless of the number of targets in the sputtering device 10.

First, the arrangement of the targets TA, TB, and TC will be described. As described above, the targets TA, TB, and TC are arranged on the sputtering device 10 so that the target normal Lt to the sputtered surface and the normal Ls to the film formation surface Ss of the substrate S is the tilt angle θ. To describe the tilt angle θ, the release angle of sputter particles SP released from the reference point Tc of the sputtered surface of the targets TA, TB, and TC, and the angle of incidence of sputter particles SP striking the film formation surface Ss of the substrate S are defined as described below. The definition of the release angle and the angle of incidence is determined in the same manner for each target. The definition of the release angle and the angle of incidence relating to the first target TA is shown below.

The angle of a straight line, which connects a closest point Pe1 on the outer circumferential edge of the substrate S that is closest to the sputtered surface TAs and a reference point Tc of sputtered surface TAs, and the target normal Lt to the sputtered surface TAs is referred to as the closest release angle θen.

The angle of a straight line, which connects the center point Pc of the substrate S and the reference point Tc of the sputtered surface TAs, and the target normal Lt on sputtered surface TAs is referred to as the center release angle θec.

The angle of a straight line, which connects a farthest point Pe2 on the outer circumferential edge of the substrate S that is farthest from the sputtered surface TAs and the reference point Tc of the sputtered surface TAs, and the target normal Lt to sputtered surface TAs is referred to as the farthest release angle θef.

The angle of a straight line, which connects the closest point Pe1 of the substrate S and the reference point Tc of sputtered surface TAs, and a normal Le1 to the film formation surface Ss extending through the closest point Pe1 is referred to as the most proximal angle of incidence θin.

The angle of a straight line, which connects the center point Pc of the substrate S and the reference point Tc of the sputtered surface TAs, and the normal Lc to film formation surface extending through the center point Pc of the substrate S is referred to as the center angle of incidence θic.

The angle of a straight line, which connects the farthest point Pe2 of the substrate S and the reference point Tc of the sputtered surface TAs, and a normal Le2 to the film formation surface Ss extending through the farthest point Pe2 is referred to as the farthest angle of incidence θif.

In this embodiment, the tilt angle θ of the three targets TA, TB, and TC is determined so that the most proximal angle of incidence θin of the three targets TA, TB, and TC is smaller than the farthest angle of incidence θif of the other targets. Further, the distance from the first target TA (reference point TC) in the normal direction of the film formation surface Ss to the film formation surface Ss is set as the target height H, and the distance from the center point Pc of the film formation surface Ss to the closest point Pe1 is set as the radius of the substrate S. Based on the target height H, radius of substrate S, and the release angle distribution, the tilt angle θ of the three targets TA, TB, and TC is specified so that the sputter particles SP are released at a relatively high release frequency at the closest release angle θen. In FIG. 3, the tilt angles θ of the first target TA and the second target TB are the same.

For example, when the sputtered surface TAs of the first target TA is formed from MgO, as shown in FIG. 2(a), the arrangement position of the first target TA is specified so that sputter particles are released at the closest release angle Oen in a range of 20° to 25° or 25° to 30° from the boundary of the release angle at which the release frequency becomes the highest. When the sputtered surface TAs of the first target TA is formed from aluminum, as shown in FIG. 2(b), the arrangement position of the first target TA is specified so that sputter particles are released at the closest release angle Ben in a range of 85° to 95° at which the release angle becomes relatively high. Further, the tilt angles θ of the three targets TA, TB, and TC are specified to values that are the same or approximate so that the each proximal angle of incidence θin of the three targets TA, TB, and TC is less than the farthest angles of incidence θif of the other targets. In this embodiment, argon gas is used as the sputtering gas of the target. That is, the sputtered surface of the target is sputtered by argon ions in the plasma generated from the argon gas.

When forming a film on a single target, for example, the first target TA, the sputter particles SP deposited on the circumferential edge of the substrate S have an angle of incidence as described below in (A) or (B) in accordance with the distance from the reference point Tc of the sputtered surface TAs to a point on the circumferential edge of the substrate S. Thus, when the substrate S rotates once, the sputter particles of (A) or (B) are deposited on the entire surface on the circumferential edge of the substrate S.

(A) Sputter particles SP having a small angle of incidence are deposited at a point of the substrate close to the first target TA, for example, the closest point Pe1.

(B) Sputter particles having a large angle of incidence are deposited at a point of the substrate distant from the first target TA, for example, the farthest point Pe2.

When film forming is terminated during a rotation cycle of the substrate S, in the final rotation of the substrate S, a portion where the sputter particles SP of (A) are not deposited or a portion where the sputter particles SP of (B) are not deposited is formed on the circumferential edge of the substrate S. As a result, the regularity in the arrangement of the sputter particles SP and, consequently, the orientation of the thin film formed by depositing the sputter particles SP may be lost in the circumferential edge of the substrate S.

Further, when film forming is performed using, for example, only the first target TA, components in the circumferential direction of the substrate S vary in accordance with the angle of rotation of the substrate S in the incidence direction of the sputter particles SP deposited on the center point Pc of the substrate. Thus, although the variations are small as compared with the incidence angle of the sputter particles SP at the circumferential edge of the substrate S, the incidence angle of sputter particles at the center point Pc of the substrate S becomes the same incidence angle only after one full rotation of the substrate S. As a result, the regularity of arrangement of the sputter particles SP and, consequently, the orientation of the thin film formed by depositing the sputter particles SP may also be lost near the center point Pc of the substrate S.

In this respect, in the first embodiment, the three targets TA, TB, and TC, which are arranged so that the most proximal angle of incidence θin of each target is smaller than the farthest angle of incidence θif of the other targets, are sputtered at the same time. Thus, the sputter particles SP having a small angle of incidence are deposited at the same time on three positions on the circumferential edge of the substrate S close to the targets TA, TB, and TC. Further, the sputter particles SP having a large angle of incidence are deposited at the same time on three positions on the circumferential edge of the substrate S distant from the targets TA, TB, and TC. Before the substrate S rotates once, the sputter particles SP of (A) and the sputter particles SP of (B) are deposited on the entire circumferential edge of the substrate S. As a result, even when the film forming is terminated in the midst of a rotation cycle, the portion on which the sputter particles SP of (A) are not deposited or the portion on which the sputter particles SP of (B) are not deposited may be reduced by using the three targets TA, TB, and TC. Accordingly, regardless of whether a desired orientation is obtained by the sputter particles SP of (A) or a desired orientation is obtained by the sputter particles SP of (B), the orientation of the thin film at the circumferential edge of the substrate S may be increased, and the uniformity of the orientation may be increased. Moreover, since the three targets TA, TB, and TC are arranged in the circumferential direction of the substrate S, even when the substrate S is rotating once, near the center point Tc of the substrate S, the sputter particles SP reach at an incidence direction at which angle components in the circumferential direction of the substrate S are the same or almost the same. As a result, the strength of orientation near the center point Tc of the substrate S may be increased.

In addition, since the three targets TA, TB, and TC are equally arranged in the circumferential direction of the substrate S, the sputter particles SP having the same angle of incidence reach the circumferential edge of the substrate SP at equal intervals. Thus, the bias in the orientation of thin film at the circumferential edge of the substrate S may be decreased, and the in-plane uniformity of the orientation may be further increased.

[Reaching Process of Sputter Particles]

The process in which the sputter particles SP released from the targets TA, TB, and TC reach the film formation surface Ss of the substrate S will now be described. The process of sputter particles SP released from the targets TA, TB, and TC reaching the film formation surface Ss of the substrate S is the same for each target. Accordingly, in the description hereafter, actions of the sputter particles SP released from the first target TA and the sputter particles SP released from the second target TB are shown, and the process in which the sputter particles SP released from the first target TA reach the film formation surface Ss will be described.

In the first target TA, the distance from the reference point Tc of the sputtered surface TAs to each one of the closest point Pel, center point Pc, and farthest point Pe2 satisfies the following relationship.

(distance from reference point Tc to farthest point Pe2)>(distance from reference point Tc to center point Pc)>(distance from reference point Tc to closest point Pe1)

The distance from the reference point Tc of the second target TB to each one of the closest point Pe1, center point Pc, and farthest point Pe2 satisfies the following relationship.

(distance from reference point Tc to closest point Pe1)>(distance from reference point Tc to center point Pc)>(distance from reference point Tc to farthest point Pe2)

Here, when the targets TA, TB, and TC are sputtered at the same time, at the closest point Pe1, the sputter particles SP released from the first target TA at the closest release angle θen reach the film formation surface Ss at the most proximal angle of incidence θin. In addition, the sputter particles SP released from the second target TB at the farthest release angle θef reach the film formation surface Ss at the farthest angle of incidence θf. At this time, the sputter particles SP released from the first target TA collide with the particles described below in (C1) and (C2) and are scattered before reaching the closest point Pe1, so that some of the particles SP do not reach the closest point Pe1.

(C1) Argon particles for releasing sputter particles SP.

(C2) Sputter particles SP released from the second target TB at the farthest release angle θef.

Further, the sputter particles SP released from the second target TB collide with the particles described below in (C3) to (C5) and are scattered before reaching the farthest point Pe1, so that some of the particles SP do not reach the closest point Pe1.

(C3) Argon particles for releasing sputter particles SP.

(C4) Sputter particles SP released from the first target TA at the farthest release angle θef.

(C5) Sputter particles SP released from the first target TA at the closest release angle θen.

As a result, the sputter particles SP reaching the film formation surface Ss at the farthest angle of incidence θif, as compared with the sputter particles SP reaching the film formation surface Ss at the most proximal angle of incidence θin, collide with more types of particles. In addition, the sputter particles SP reaching the film formation surface Ss at farthest angle of incidence θif are long in distance to reach the film formation surface Ss and are more likely to be scattered by the collisions described above. Accordingly, the sputter particles SP reaching the film formation surface Ss at the most proximal angle of incidence θin are more likely to be deposited on the film formation surface Ss as compared with the sputter particles SP reaching the film formation surface Ss at the farthest angle of incidence θif. That is, at the closest point Pe1, sputter particles smaller in the angle of incidence are more likely to be deposited on the film formation surface Ss as compared with sputter particles larger in the angle of incidence.

Further, at the farthest point Pe2, the sputter particles SP released from the first target TA at the farthest release angle θef reach the film formation surface Ss at the farthest angle of incidence θif, and the sputter particles SP released from the second target TB at the closest release angle θen reach the film formation surface Ss at the most proximal angle of incidence θin. That is, at the farthest point Pe2, due to the same reasons as the closest point Pe1, the sputter particles SP of the most proximal angle of incidence θin are more likely to be deposited. That is, at the farthest point Pe2, the sputter particles smaller in the angle of incidence are more likely to be deposited on the film formation surface Ss as compared with the sputter particles larger in the angle of incidence.

In this embodiment, for the sputter particles SP released at a relatively high release frequency to be released at the closest release angle θen, the tilt angle θ of the three targets TA, TB, and TC is specified. Thus, the sputter particles released at a relatively high release frequency may reach the film formation surface Ss at the most proximal angle of incidence θin. In such a configuration, more sputter particles SP having a small angle of incidence may reach the circumferential edge of substrate S. As a result, the occupying rate of sputter particles SP reaching the film formation surface Ss at a small angle of incidence becomes higher throughout the entire film formation period in the deposits on the substrate circumferential edge. Thus, the orientation of the thin film on the substrate circumferential edge is increased. In addition, at any point of the film formation surface Ss, the angle of incidence is uniform during the entire film formation period, and the in-plane uniformity of orientation in the thin film on the film formation surface Ss is further increased.

In the present embodiment, the tilt angle θ is determined so that the sputter particles SP released at a release angle of high release frequency may reach a wide range in the film formation surface Ss. In such a configuration, the in-plane uniformity of the film thickness on the film formation surface Ss may be further increased.

### EXAMPLE 1

An example using the sputtering device 10 will now be described. An MgO film of example 1 was obtained by a film forming process under the condition described below using the sputtering device 10. In regard to the MgO film of example 1, necessary points within the plane of the substrate S were measured by X-ray diffraction process to determine the strength at the MgO (200) peak (2θ=49.7°) showing (001) orientation. Further, using the sputtering device including a single MgO target fixed at the tilt angle θ of 22°, the film forming pressure was changed to 10 mPa, 19 mPa, 82 mPa, and 157 mPa with the other conditions being the same as example 1 to obtain the MgO film of comparative example 1. In the same manner as in example 1, the MgO (200) peak strength showing (001) orientation was measured by the X-ray diffraction process.

number of film forming cathodes: 3

substrate S: silicon substrate (diameter: 8 inches)

target: MgO target (diameter: 5 inches)

target height H: 190 mm

distance W from reference point Tc to center point Pc as viewed in direction of normal Lc: 175 mm

substrate temperature: room temperature

sputtering gas: Ar

tilt angle θ: 22°

film forming pressure: 19 mPa, 82 mPa, 306 mPa

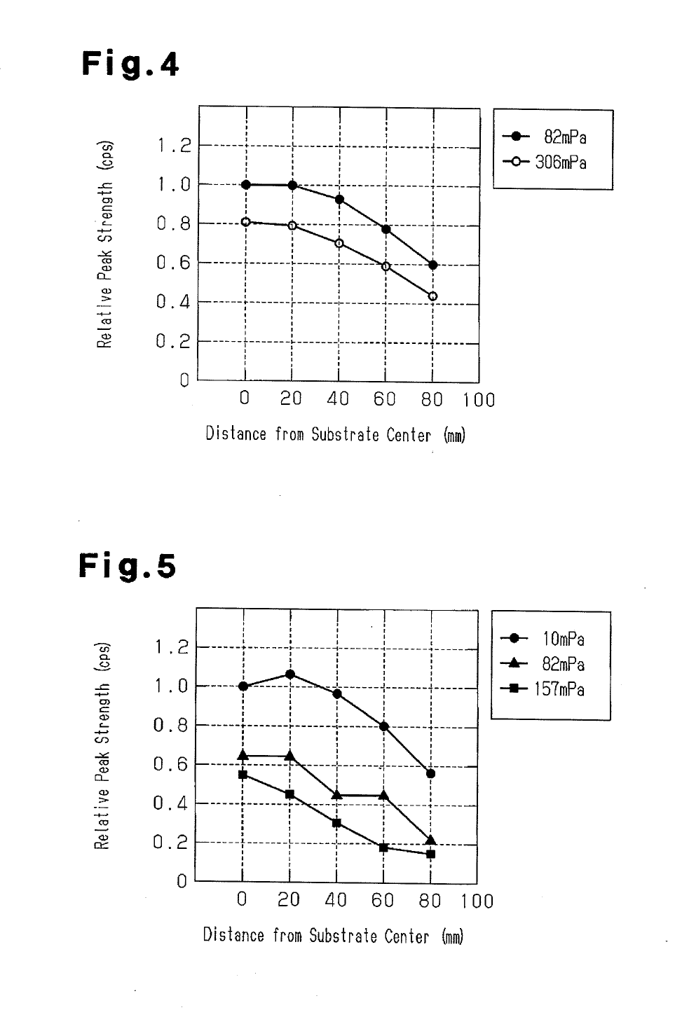

FIG. 4 is a graph relatively showing the strength of MgO (200) peak of the MgO films formed at each film forming pressure in example 1 (82 mPa, 306 mPa) for each distance from the center point Pc of the substrate S. The peak strength at the substrate center of the MgO film formed under a low pressure condition (82 mPa) is 1.0. FIG. 5 is a graph relatively showing the strength of MgO (200) peak of the MgO films formed at each film forming pressure in comparative example 1 (10 mPa, 82 mPa, 157 mPa) for each distance from center point Pc of the substrate S. In comparative example 1, the peak strength at the substrate center of the MgO film formed under a low pressure condition (10 mPa) is 1.0.

As shown in FIG. 4, throughout the entire substrate S, the peak strength of the MgO film formed under the low pressure condition (82 mPa) is higher than the peak strength of the MgO film formed under the high pressure condition (306 mPa). As shown in FIG. 5, throughout the entire substrate S, the peak strength of the MgO film formed under the low pressure condition (10 mPa) is higher than the peak strength of the MgO film formed under the high pressure condition (157 mPa). In both of example 1 and comparative example 1, as the film forming pressure increases, the strength of the MgO (200) peak decreases, while the distribution uniformity of the peak strength tends to decrease. In other words, as the film forming pressure decreases, the strength of the MgO (200) peak increases, and the distribution of the peak strength tends to become uniform.

When the peak strength distribution of the MgO film at the film forming pressure of 82 mPa in example 1 is PD1 and the peak strength distribution of the MgO film at the same film forming pressure of 82 mPa in comparative example 1 is PD2, the substrate in-plane uniformity of the peak strength distribution PD1 is compared with the substrate in-plane uniformity of the peak strength distribution PD2. In the peak strength distributions PD1 and PD2, the in-plane uniformity is calculated in the process described below (Max/Min process). More specifically, the peak strength distribution PD (PD1, PD2) is expressed as PD=((Max−Min)/(Max+Min))×100(%), where Max is the maximum value of the peak strength and Min is the minimum value of the peak strength. As the absolute value of PD decreases, the peak strength distribution is improved.

In example 1, the maximum value Max1 of the peak strength is 1 when the distance from the substrate center is 0 mm, and the minimum value Minl is 0.6029% when the distance from the substrate center is 80 mm. Accordingly, the peak strength distribution PD1 is ((1.0−0.6029)/(1.0+0.6029))×100=24.770. In comparative example 1, the maximum value Max2 of the peak strength is 0.6364 when the distance from the substrate center is 0 mm, and the minimum value Min2 is 0.2286% when the distance from the substrate center is 80 mm. Accordingly, the peak strength distribution PD2 is ((0.6364−0.2286)/(0.6364+0.2286))×100=47.14%. Evidently, the peak strength distribution in example 1 is better than the peak strength distribution in comparative example 1.

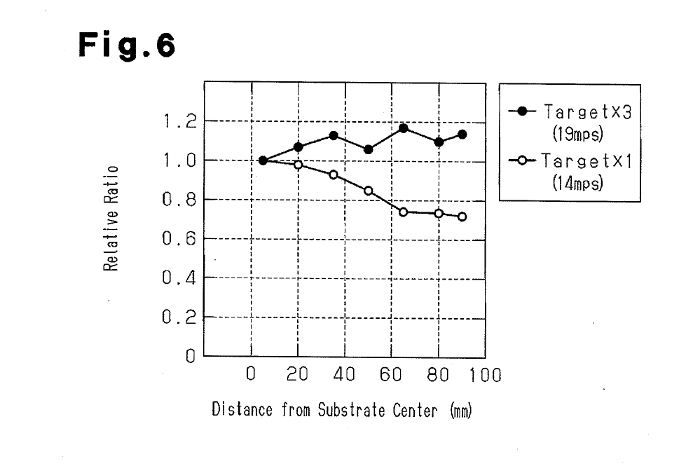

FIG. 6 is a graph relatively showing the MR ratio of the substrate S including the MgO film in example 1 obtained at the film forming pressure of 19 mPa and the MR ratio of the substrate S including the MgO film in comparative example 1 obtained at film forming pressure of 14 mPa for each distance from the center point of the substrate S. Each MR ratio at the center point Pc of the substrate S is standardized as 1.0.

The Max/Min method is used to calculate the strength distribution (MD) of MR ratio in example 1 and comparative example 1. In example 1, the maximum value of MR ratio is 1.165 when the distance from the substrate center is 65 mm, and the minimum value of MR ratio is 1.0 when the distance from the substrate center is 5 mm. Accordingly, the MR ratio strength distribution MD1 in example 1 is ((1.165−1.0)/(1.165+1.0))×100=7.621%. In comparative example 1, the maximum value of the MR ratio is 1.0 when the distance from the substrate center is 5 mm, and the minimum value of the MR ratio is 0.7191 when the distance from the substrate center is 90 mm. Accordingly, the MR ratio strength distribution MD2 in comparative example 1 is ((1.0−0.7191)/(1.0+0.7191))×100=16.33%. As described above, it is apparent that in example 1 and comparative example 1 including the MgO films formed substantially the same film forming pressure, the MR ratio strength distribution MD1 in example 1 is more favorable than the MR ratio strength distribution MD2 in comparative example 1.

### Second Embodiment

A sputtering device according to a second embodiment of the present invention will now be described with reference to FIGS. 1 and 2.

The sputtering device of the second embodiment particularly specifies the tilt angle θ for the targets TA, TB, and TC in the sputtering device 10 of the first embodiment. Otherwise, the structure of the second embodiment is the same as the sputtering device 10. The tilt angle θ of the sputtering device in the second embodiment is set in a range expressed by expression (1), which is shown below.

−50°+φ<θ<−35°+φ Expression (1)

In expression (1), the angle φ is expressed by the equation of

φ=arctan(W/H)

where W represents the distance in the horizontal direction from the center point Pc of the film formation surface of the substrate S to the center point (reference point Tc) of the sputtered surface of the target T, and H represents the distance in the vertical direction from the center point Pc of the film formation surface of the substrate S to the center point (reference point Tc) of the sputtered surface, that is, the target height. The angle φ, which is less than 90°, is the angle of a straight line, which extends through the center point Pc of the film formation surface and the center point (reference point Tc) of the sputtered surface, and a normal (that is, the substrate normal Ls) extending through the center point Pc of the film formation surface.

As illustrated in FIG. 2, in the target of which the main component is MgO, from a point at which the sputter gas particles strike the sputtered surface, a large amount of sputter particles are released at the release angle θe of about 20° to 30°. In particular, the amount of sputter particles becomes greatest when released at the release angle θe of about 25°. The proximity of the release angle Oe at which a large amount of sputter particles are released is a ranged in which the variation in the release frequency per release angle is relatively small. In this configuration, the tilt angle θ is set so that the release angle θe of the maximum release amount of sputter particles is directed to the film formation surface. Thus, the sputter particles may be stably supplied over the entire film formation surface. This improves the uniformity of film thickness of the MgO film.

### EXAMPLE 2

An example using the sputtering device will now be described. An MgO film of example 2 was obtained by a film forming process under the condition described below using the sputtering device 10. The film thickness was measured at a number of given points within the plane of the MgO film formed in example 2, and the distribution was calculated.

number of film forming cathodes: 3

substrate S: silicon substrate (diameter: 8 inches)

target: MgO target (diameter: 5 inches)

target height H: 210 mm

distance W from reference point Tc to center point Pc as viewed in the direction of normal Lc: 190 mm

substrate temperature: room temperature

sputtering gas: Ar

angle φ: 42.13°

tilt angle: −7.87°<θ<7.13°

film forming pressure: 20 mPa

### EXAMPLE 3

An MgO film of example 3 was obtained by changing the conditions of the target height H, distance W, angle φ, and tilt angle θ as described below. Otherwise, the conditions were the same as example 1. The film thickness was measured at a number of given points within the plane of the MgO film formed in example 3, and the distribution was calculated. Further, in the same manner as in example 1, the strength of the MgO (200) peak indicating the (001) orientation was calculated by the X-ray diffraction process.

target height H: 230 mm

distance W from reference point Tc to center point Pc as viewed in the direction of normal Lc: 190 mm

angle φ: 39.56°

tilt angle θ: −10.44<θ<4.56

film forming pressure: 20 mPa

Further, an MgO film of comparative example 3 was obtained only by changing the tilt angle θ of example 2 to −7.87°>θ, 7.13°<θ, which are not included in the range of expression (1). Further, an MgO film of comparative example 3 was obtained only by changing the tilt angle θ of example 3 to −10.44>θ, 4.56<θ, which are not included in the range of expression (1). The film thickness was measured at a number of given points within the plane of the MgO film formed in comparative example 2 and comparative example 3, and the distribution was calculated. Further, in the same manner as in comparative example 1, the strength of the MgO (200) peak indicating the (001) orientation was calculated by the X-ray diffraction process.

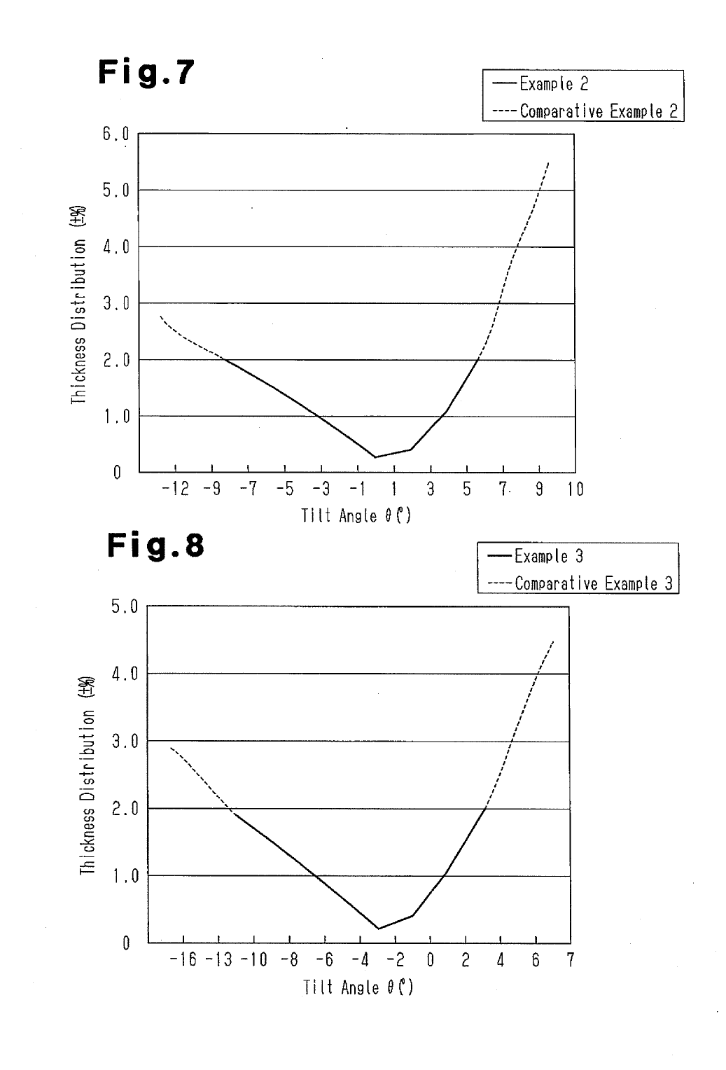

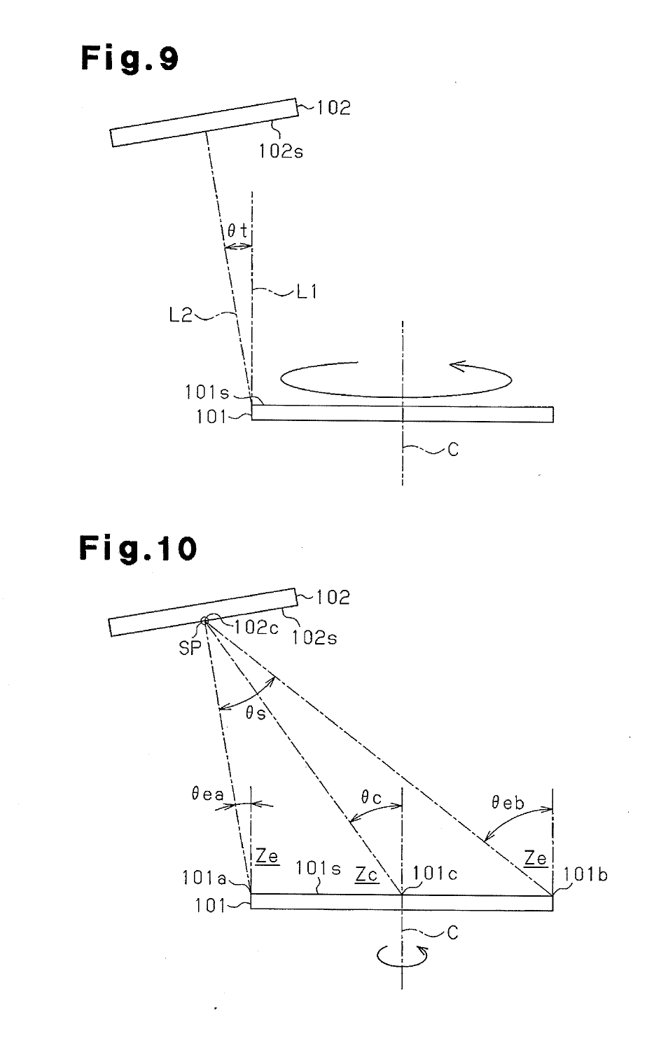

FIG. 7 shows the film thickness distribution of the MgO film formed at each tilt angle θin example 2 and comparative example 2, and FIG. 8 shows the film thickness distribution of MgO film formed at each tilt angle θin example 3 and comparative example 3.

As shown in FIGS. 7 and 8, the value of the film thickness distribution of the MgO film formed when the tilt angle θ is set outside the range specified by expression (1) is greater than the value of the film thickness distribution of the MgO film formed when the tilt angle θ is in the range specified by expression (1). That is, the sputtering device including a target of which the tilt angle θ is specified in expression (1) allows for the film thickness distribution of the MgO film to be preferable.

Further, as in example 2 shown in FIG. 7 and example 3 shown in FIG. 8, when setting the same tilt angle θ for the three targets and forming MgO films with different tilt angles θ, a favorable film thickness uniformity within ±1% was recognized for the tilt angle θin the range of −50+φ<θ<−35+φ. In addition, in the MgO film formed in the same range of the tilt angle θ, the in-plane distribution of the substrate S in the relative peak strength of the orientation was recognized as being improved to ±10% to ±15% or less as compared with example 1.

Even when the MgO film is formed by laminating MgO particles having the same orientation, if there is a variation in the thickness within the plane of the MgO film, the relative peak strength increases at a portion where the film thickness is relatively large, and the relative peak strength decreases at a portion where the film thickness is relatively small. Thus, as described above, by improving the film thickness distribution of the MgO film, the orientation can be improved. That is, the sputtering device of the present embodiment allows for the formation of an MgO film having satisfactory orientation.

The sputtering device of the second embodiment is a sputtering device including the three targets TA, TB, and TC. However, as described in the first embodiment, the number of targets contributes greatly to the orientation of the MgO film. Accordingly, when it is particularly significant that the film thickness distribution be improved or when the orientation strength is ensured by improving the orientation accompanied by film thickness distribution, the sputtering device including a single target so as to satisfy the relationship of expression (1) may be realized.

As described above, the sputtering device of each of the above embodiment has the advantages listed below.

(1) In each embodiment, in the circumferential direction of the substrate S, the three targets TA, TB, TC are arranged so that the most proximal angle of incidence θin of each of the targets TA, TB, and TC is smaller than the farthest angle of incidence θif of the other two targets. As a result, sputter particles having a small angle of incidence are simultaneously deposited in portions on the circumferential edge of the substrate S close to the substrate S of each target, and sputter particles having a large angle of incidence are simultaneously deposited in portions on the circumferential edge of the substrate S far from the substrate S of each target. Thus, even in the midst of one rotation of the substrate S, sputter particles of a small angle of incidence or sputter particles of a large angle of incidence are deposited on the entire circumferential edge of the substrate S. Hence, even if the film formation is terminated in the midst of a rotation cycle, it is possible to reduce the area of the portions where sputter particles of small angle of incidence are not deposited and the area of the portions where sputter particles of a large angle of incidence are not deposited by using the three targets TA, TB, and TC. As a result, regardless of whether the desired orientation is obtained by sputter particles of a small angle of incidence or by sputter particles of a large angle of incidence, the strength of orientation on the circumferential edge of the substrate may be improved.

(2) The plurality of targets are arranged in the circumferential direction of the substrate S. Thus, even in the midst of one rotation of the substrate S, in the angle of incidence of the sputter particles that reach the vicinity of the center point of the substrate S, the angle components along the circumferential direction of the substrate S become uniform by using the plurality of targets. As a result, the strength of orientation near the center point of the substrate S may also be improved.

(3) In the second embodiment, three targets TA, TB, and TC are arranged so that the tilt angle θ satisfies the relationship of −50+φ<θ<−35+φ. As a result, the peak strength of orientation in the magnesium oxide film may be improved, and the uniformity of film thickness distribution may be assured.

(4) In the film forming process, the internal pressure of the vacuum chamber is set at 10 mPa or greater and 130 mPa or less. As a result, the film forming pressure is 10 mPa or greater and 130 mPa or less. Thus, the uniformity of distribution of orientation in the magnesium oxide film may be realized at a higher orientation strength.

(5) The tilt angle θ of the normal Ls to the film formation surface Ss of the substrate S and the normal Lt to the sputtered surface of the targets TA, TB, and TC is the same for the targets TA, TB, and TC. As a result, when starting the film forming process or when terminating the film forming process, the same orientation may be obtained by the three targets TA, TB, and TC arranged in the circumferential direction of the substrate S. Hence, the in-plane uniformity of the orientation may be further improved.

(6) The plurality of targets TA, TB, and TC are arranged at equal intervals on the circumferential edge of the substrate S. As a result, the sputter particles having the same angle of incidence reach the circumferential edge of the substrate S at equal intervals. This further reduces biasing in the orientation at the circumferential edge of the substrate S, and the in-plane uniformity of the orientation may be further includes.

The above embodiments may be modified as described below.

As long as each most proximal angle of incidence of two or more targets arranged in the circumferential direction of the substrate S is smaller than the farthest angles of incidence of the other targets, the two or more targets do not have to be arranged at equal intervals in the circumferential direction of the substrate S. This configuration also obtains advantages (1) to (5), which are described above. Specific examples are described with regard to the improvement of the film thickness distribution and orientation in an 8-inch substrate. However, this also applied to substrates of different sizes.

The tilt angle θ does not have to be accurately the same as long as the tilt angle θ results in the most proximal angle of incidence θin of sputter particles SP released from each of a plurality of targets being smaller than the farthest angle of incidence θif of the other targets.

The pressure in the film forming process may be outside the range of 10 mPa or greater and 130 mPa or less and may be a range in which the sputter particles SP of the most proximal angle of incidence θin are hardly scattered and the sputter particles of the farthest angle of incidence θif may be easily scattered.

The diameter of the substrate S, the diameter of the target, the target height, and the distance W are not particularly specified. As long as each most proximal angle of incidence of each of two or more targets arranged in the circumferential direction of the substrate are smaller than the each farthest angles of incidence of the other targets, the conditions may be changed freely within the range in which the tilt angle θ satisfies the relationship of expression (1).

The sputtering gas is not limited to rare gas and may be a mixture of rare gas and oxygen or the like. Instead of a magnesium oxide target (MgO), for example, a magnesium target (Mg) may be used, and an (001) orientation film of magnesium oxide may be formed on a substrate by using such a gas mixture. In this case, the surface of the magnesium target is oxidized by the mixed gas (oxygen), and the surface is magnesium oxide, and the release angle is the same as in the MgO target. That is, the magnesium target in this case is substantially sputtered as an MgO target.

From the viewpoint of in-plane uniformity of the peak strength of orientation, as long as two or more targets are arranged in the circumferential direction of the substrate S, the number of targets is not specified. Further, as long as the plurality of targets are formed from MgO, other targets formed from different materials may also be used. For example, in addition to two or more targets formed from MgO, a single target formed from Mg may be used. In this configuration, after forming an Mg film as an underlayer for an MgO film, the MgO film may be formed on the Mg film without unloading the substrate from the vacuum chamber.

From the viewpoint of in-plane uniformity of the peak strength of orientation, the tilt angle θ does not have to be included in the range of −50+φ<θ<−35+φ. It is only required that the tilt angle θ results in the most proximal angle of incidence θin of sputter particles SP released from each of the targets being smaller than the farthest angle of incidence θif of the other targets.

1. A sputtering device comprising:
a vacuum chamber accommodating a substrate stage that rotates a disk-shaped substrate, which includes a film formation surface, in a circumferential direction of the substrate; and
a target arranged in the circumferential direction of the substrate and including a sputtered surface formed from magnesium oxide and exposed to the interior of the vacuum chamber,
wherein
an angle of a normal to the film formation surface of the substrate and a normal to the sputtered surface of the target is defined as an inclination angle θ,
the inclination angle θ of the target is 0° when the sputtered surface is opposed to the film formation surface and the normal to the sputtered surface is parallel to the normal to the film formation surface,
the inclination angle θ is positive when the sputtered surface is directed inward into the film formation surface,
the inclination angle θ is negative when the sputtered surface is directed outward from the film formation surface,
when a height from a center of the substrate to a center of the target is H, and a width from the center of the substrate to the center of the target is W, an angle φ expressed by the height H and the width W is defined as φ=arctan(W/H), and
the target is arranged so that the inclination angle θ of the target satisfies the relationship of −50+φ<θ<−35+φ.

2. The sputtering device according to claim 1, wherein a pressure in the interior of the vacuum chamber is 10 mPa or greater and 130 mPa or less.

3. A sputtering device comprising:
a vacuum chamber accommodating a substrate stage that rotates a disk-shaped substrate, which includes a film formation surface, in a circumferential direction of the substrate; and
a plurality of targets arranged in the circumferential direction of the substrate, each of the targets including a sputtered surface formed from magnesium oxide and exposed to the interior of the vacuum chamber, and wherein
a point on a circumferential edge of the substrate that is closest to a center point of the sputtered surface is defined as a proximal point,
an angle of a straight line, extending through the center point of the sputtered surface and the proximal point of the substrate, and the film formation surface of the substrate is defined as a most proximal angle of incidence,
a point on the circumferential edge of the substrate that is farthest from the center point of the sputtered surface is defined as a far point,
an angle of a straight line, extending through the center point of the sputtered surface and the far point of the substrate, and the film formation surface of the substrate is defined as a farthest angle of incidence, and
the plurality of targets are arranged so that the most proximal angle of incidence of each of the targets is smaller than the farthest angle of incidence of the other targets, and the plurality of targets are sputtered at the same time.

4. The sputtering device according to claim 3, wherein
an angle of a normal to the film formation surface of the substrate and a normal to the sputtered surface of the targets is defined as an inclination angle θ,
the inclination angle θ of the target is 0° when the sputtered surface is opposed to the film formation surface and the normal to the sputtered surface and the normal to the film formation surface are parallel to each other,
the inclination angle θ is positive when the sputtered surface is directed inward into the film formation surface,
the inclination angle θ is negative when the sputtered surface is directed outward from the film formation surface,
when a height from a center of the substrate to a center of each of the targets is H, and a width from the center of the substrate to the center of each of the targets is W, an angle φ expressed by the height H and the width W is defined as φ=arctan(W/H), and
the target is arranged so that the inclination angle θ of the target satisfies the relationship of −50+φ<θ<−35+φ.

5. The sputtering device according to claim 3, wherein a pressure in the interior of the vacuum chamber is 10 mPa or greater and 130 mPa or less.

6. The sputtering device according to claim 3, wherein an inclination angle that is an angle of a normal to the film formation surface of the substrate and a normal to the sputtered surface of each of the targets is the same in the plurality of targets.

7. The sputtering device according to claim 3, wherein the plurality of targets are arranged at equal intervals in the circumferential direction of the substrate.

8. The sputtering device according to claim 4, wherein a pressure in the interior of the vacuum chamber is 10 mPa or greater and 130 mPa or less.

9. The sputtering device according to claim 4, wherein the inclination angle is the same in the plurality of targets.

10. The sputtering device according to claim 4, wherein the plurality of targets are arranged at equal intervals in the circumferential direction of the substrate.
